(19) United States
(12) Patent Application Publication
(10) Pub. No.: US 2017/0094812 A1
(43) Pub. Date: Mar. 30, 2017

(54) METHOD OF MODIFYING A DATUM SURFACE FOR IMPROVED PART OFFSET CONTROL

(71) Applicant: Apple Inc., Cupertino, CA (US)

(72) Inventors: William F. Leggett, San Francisco, CA (US); Michelle R. Goldberg, Sunnyvale, CA (US)

(21) Appl. No.: 15/148,554

(22) Filed: May 6, 2016

Related U.S. Application Data
(60) Provisional application No. 62/234,222, filed on Sep. 29, 2015.

(51) Int. Cl. H05K 5/00; G06F 1/16; H05K 5/02

(52) U.S. Cl. CPC H05K 5/0013; H05K 5/0217; G06F 1/1616; G06F 1/1626

(57) ABSTRACT

Devices and techniques for improving the fit between multiple components of a part are described. In particular embodiments, the techniques involve providing features that allow for offset adjustments of components during an assembly process after the components have been already been machined to final dimension. The features can protrude from a mating or datum surface of one or both of the components. The heights of the features can be modified so as to modify a dimension of the mating surface, providing minor offset control for critical dimensions during an assembly process. In some cases, the features are provided on a separate insert piece that can be easily modified and replaced if necessary.

### CROSS REFERENCE TO RELATED APPLICATION

This application claims the benefit of priority under 35 U.S.C §119(e) to U.S. Provisional Application No. 62/234,222, entitled “METHOD OF MODIFYING A DATUM SURFACE FOR IMPROVED PART OFFSET CONTROL,” filed on Sep. 29, 2015, which is incorporated by reference herein in its entirety.

### FIELD

The described embodiments relate generally to alignment of component parts of an electronic device. More particularly, the present embodiments relate to utilizing a modifiable piece that adjusts a datum surface to correct alignment between component parts during assembly of the electronic device.

### BACKGROUND

Electronic devices generally contain multiple components, such as multiple housing components, that fit together to make a final assembled part. Each one of the components is manufactured to have specific dimensions that are within allowable tolerances based on limitations of the manufacturing equipment and processes. If, however, multiple components are assembled together to form a complex three dimensional part, individual tolerances will build up, resulting in misalignments or offsets between components. These misalignments or offsets can affect a cosmetic appearance or functional purpose of the electronic device. High value products can have higher demands on cosmetic appearance, in which case aesthetically pleasing and close fitting components are of critical importance. Therefore what are needed are improved techniques for compensating for manufacturing related tolerances and offsets.

### SUMMARY

This paper describes various embodiments that relate to manufacturing techniques for improving the fit between multiple components of a part. In particular embodiments, the techniques involve providing features that allow for minor offset adjustment of components after the components have been already been machined to final dimensions.

According to one embodiment, a method of adjusting an offset related to a first component and a second component is described. The first component is configured to couple with the second component. The method includes pre-assembling the first component with the second component. The first component includes a mating surface having a protruding feature. The method also includes measuring an offset value related to the first component and the second component. The method further includes modifying the mating surface by reducing a height of the protruding feature so as to reduce the offset value to a final offset value.

According to another embodiment, an enclosure for an electronic device is described. The enclosure includes a first section having a first mating surface with a protruding feature. The enclosure also includes a second section having a second mating surface configured to mate with the first mating surface. A height of the protruding feature is adjusted such that a first external surface of the first section and a second external surface of the second section are aligned in accordance with a reference surface.

According to a further embodiment, a method of assembling an enclosure for an electronic device is described. The enclosure includes a first section and a second section. The method includes pre-assembling the enclosure by contacting a first mating surface of the first section with a second mating surface of the second section. The first mating surface includes a protruding feature. The method also includes determining a degree of misalignment between the first section and the second section when the enclosure is pre-assembled. The method additionally includes modifying the first mating surface by reducing a height of the protruding feature. The height is reduced to an extent that reduces the degree of misalignment. The method further includes repeating the pre-assembling, determining and modifying until a desired degree of misalignment is achieved.

These and other embodiments will be described in detail below.

### BRIEF DESCRIPTION OF THE DRAWINGS

The disclosure will be readily understood by the following detailed description in conjunction with the accompanying drawings, wherein like reference numerals designate like structural elements.

FIG. 1 shows perspective views of devices that can be manufactured using the techniques described herein.

FIG. 2 shows a perspective view and a partial cross section view of an enclosure for a portable computer having two sections.

FIG. 3 shows a partial cross section view of the enclosure of FIG. 2 showing an offset related to the two sections.

FIGS. 4A-4D show cross section perspective views the enclosure having a mating surface being modified to address offset problems.

FIGS. 5A-5C show perspective views of portable computers having modified mating surfaces in accordance with different embodiments.'

FIGS. 6A-6B show cross section views of an enclosure with modified mating surfaces that include openings for fasteners.

FIG. 7 shows a perspective view of and a partial cross section view of track pad assembly and an adjustable stop in accordance with some embodiments.

FIG. 8 shows a partial cross section view of an electronic device having an insert piece used in conjunction with a fastener to provide critical dimension adjustments.

FIG. 9 shows a flowchart indicating a process for adjusting a datum surface for reducing an offset related to a first component and a second component of a part.

### DETAILED DESCRIPTION

Reference will now be made in detail to representative embodiments illustrated in the accompanying drawings. It should be understood that the following descriptions are not intended to limit the embodiments to one preferred embodiment. To the contrary, it is intended to cover alternatives, modifications, and equivalents as can be included within the spirit and scope of the described embodiments as defined by the appended claims.

The following disclosure relates to methods for controlling the alignment or offset between multiple components of a part. The components can take the form of mating housing components, internal mounting components, or other components associated with an electronic device that require precise alignment for cosmetic or functional purposes. Currently, surface mismatch, or offset, is limited by the tolerances of the manufacturing process as well as assembly variability. Some applications, such as those with tight offset controls for cosmetic or critical functional purposes, conventional manufacturing tolerances can build up to unacceptable levels, leading to low manufacturing throughput.

The techniques described herein involve modifying a datum surface, such as a mating surface, of a component so as to improve the fit of the component to another component or adjust the position of the component in relation to surrounding components. In some cases, this involves providing a protruding feature on the mating surface, where a height of the protruding feature can be modified to compensate for an offset in a particular dimension. The protruding feature can be part of the mating surface itself, or can be on a separate and replaceable insert piece that is positioned on mating surface.

The techniques can be used to provide small adjustments for fine offset control. For example, the adjustments can be on the order of micrometers. In some embodiments, the techniques are implemented to finely align sections of an enclosure, such as an electronic device enclosure. In some embodiments, the techniques are implemented to provide precise relative positions for different functional components of an electronic device.

Methods described herein are well suited for providing cosmetically appealing and/or functional parts of consumer products. For example, the methods described herein can be used in the manufacture of enclosures or portions of enclosures for electronic devices, such as computers, portable electronic devices, wearable electronic devices and electronic device accessories, such as those manufactured by Apple Inc., based in Cupertino, California.

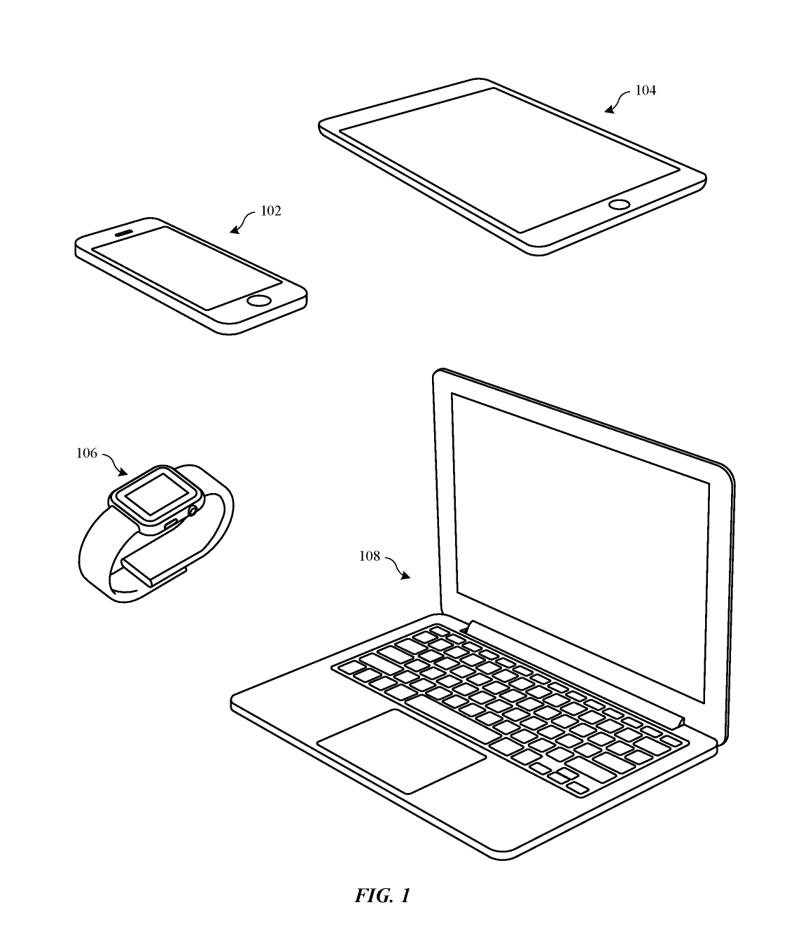

These and other embodiments are discussed below with reference to FIGS. 1-9. However, those skilled in the art will readily appreciate that the detailed description given herein with respect to these Figures is for explanatory purposes only and should not be construed as limiting.

The methods described herein can be used during the assembly of any of a number of types of consumer products. In some embodiments, the consumer products are electronic devices, such as those shown in FIG. 1, which shows portable phone 102, tablet computer 104, smart watch 106 and portable computer 108. Each of devices 102, 104, 106 and 108 includes an enclosure for housing internal electronic components. Each enclosure can include various sections, which can be made of metal, plastic, glass, etc. These various sections are securely coupled together to form a complete and aesthetically appealing enclosure.

The surfaces contours of the enclosures of devices 102, 104, 106 and 108 are often smooth and continuous, even across the different sections, in order to create visually and tactilely appealing exterior surfaces. This means that any offsets between the various sections should be tightly controlled during manufacturing and assembly processes. The offset control techniques described herein can be used to form continuous and cosmetically appealing contour surfaces for enclosure of devices 102, 104, 106 and 108.

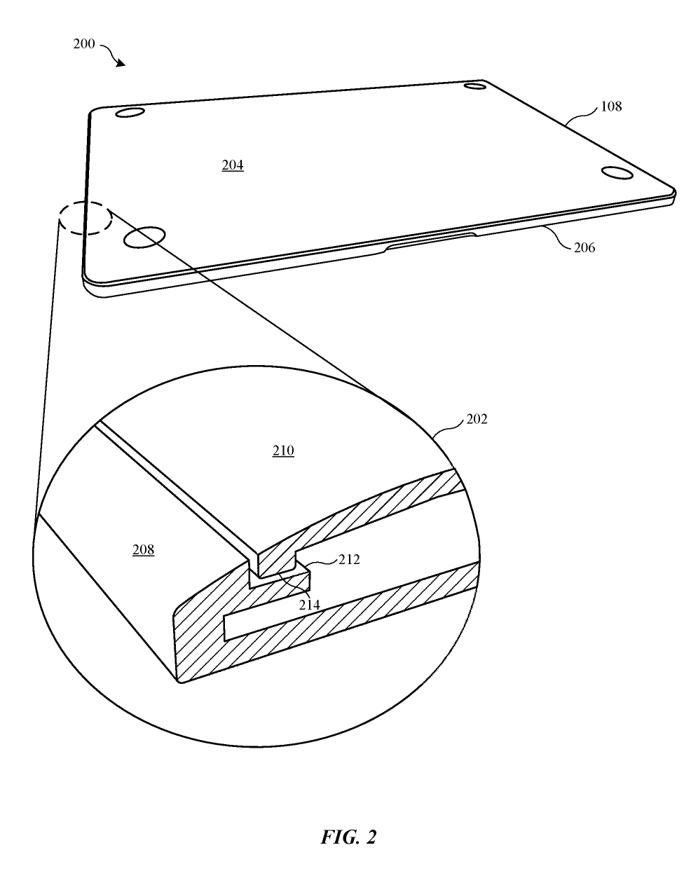

FIG. 2 shows perspective view 200 and partial cross section view 202 of portable computer 108. Perspective view 200 illustrates a bottom view of portable computer 108 showing base 204, which can be pivotally coupled with lid 206. Base 204 can house various electronic components and lid 206 can include a display. Partial cross section view 202 shows that base 204 includes first section 208 and second section 210 that are coupled together at first mating surface 212 of first section 208 and second mating surface 214 of second section 210. Note than first mating surface 212 and second mating surface 214 can each be referred to as datum surfaces. The material composition of one or both of first section 208 and second section 210 can include any suitable material for an enclosure of an electronic device, such as metal (e.g., aluminum alloys, steel), plastic or other rigid materials. In order to create a continuous exterior contoured surface to base 204, the offset between first section 208 and second section 210 should be very small or zero.

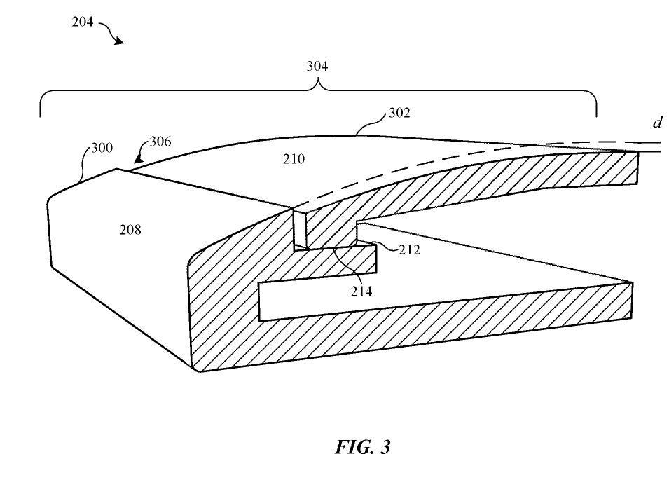

To illustrate, FIG. 3 shows a partial cross section view of base 204 where second section 210 has a negative offset with respect to first section 208. In particular, second exterior surface 302 of second section 210 is recessed with respect to first exterior surface 300 of first section 208 by distance d. That is, distance d corresponds to an amount of offset that prevents second exterior surface 302 from combining with first exterior surface 300 to from a continuous exterior surface 304 of base 204. If distance d is large enough, the offset will be visibly and/or tactilely noticeable to a user, detracting from the aesthetic appearance and tactile quality of portable computer 108. In some cases, distance d (e.g., on the scale of micrometers) can be as very small and still be noticeable. This offset can be due to inherent tolerances in the manufacturing processes that lead to slightly different dimensional variations in each of first section 208 and second section 210. As such, when first mating surface 212 is mated with second mating surface 214, first exterior surface 300 will be offset with respect to second exterior surface 302 at junction 306 between first section 208 and second section 210.

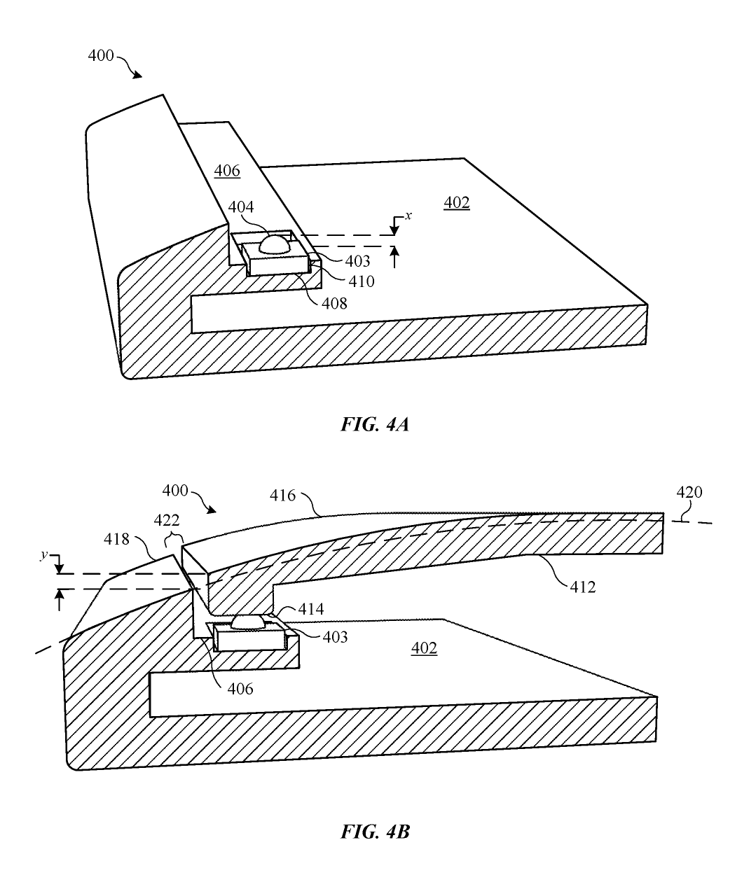

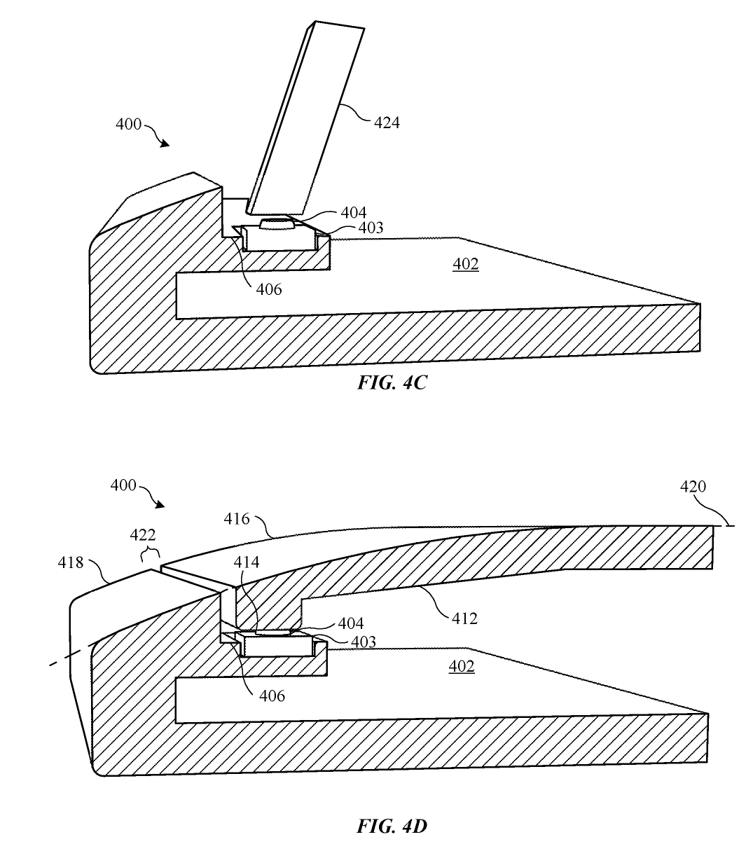

FIGS. 4A-4D show cross section perspective views of base 400 that has been modified to address the above-described offset problems. FIG. 4A shows first section 402, which includes first mating surface 406 that is configured to a mate with a corresponding section mating surface of a second section (not shown). First mating surface 406 has been modified by the addition of insert piece 403, which includes protruding feature 404 that protrudes from the remainder of mating surface 406. For example, if first mating surface 406 is substantially planar, protruding feature 404 extends above this substantially planar first mating surface 406, thereby modifying first mating surface 406. In particular, protruding feature 404 protrudes a height x from first mating surface 406 of first section 402.

In some embodiments, insert piece 403 is made of a material that is more deformable than that of first section 402. This allows protruding feature 404 of insert piece 403 to be deformed during a subsequent modification process, described below. In a particular embodiment, insert piece 403 is comprised of a thermoplastic material that becomes pliable when heated and solidifies upon cooling. In other embodiments, insert piece 403 is comprised of a metal material, such as aluminum. The material of insert piece 403 can be chosen, in part, by the chosen method of modification process.

In order to accommodate insert piece 403 within first section 402, pocket 408 is formed within first section 402, which corresponds to a recess within first mating surface 406. Pocket 408 can be formed using any suitable method, including any of a number of suitable machining processes. The shape and size of pocket 408 can be chosen in accordance with a size and shape of insert piece 403. Pocket 408 has walls 410 that can prevent excessive lateral movement of insert piece 403 during the subsequent modification process. In some embodiments, insert piece 403 is secured within pocket 408 using, for example, an adhesive. In other embodiments, insert piece 403 positioned within pocket 408 without being secured to first section 402.

At FIG. 4B, second section 412 is positioned with respect to first section 402 in a pre-assembly process. In particular, second mating surface 414 is mated with first mating surface 406 of first section 402. Since first mating surface 406 includes protruding feature 404, second exterior surface 416 of second section 412 is positively offset with respect to first exterior surface 418 of first section 402 by distance y—which can be measured during the pre-assembly process with high accuracy using, for example a camera, laser measurement system or other suitable measurement system. Without protruding feature 404, second exterior surface 416 would be negatively offset (receded) with respect to first exterior surface 418. Optimally, distance y is such that first exterior surface 418 and second exterior surface 416 cooperate to form a continuous reference surface 420. Reference surface 420 can correspond to a desired final shape or contour. Distance y will depend on the curvature of reference surface 420 and the width of gap 422 between first section 402 and second section 412. In some embodiments, an optimal or desired distance y is zero or near zero. As shown, reference surface 420 can be curved to form a particular three-dimensional contour for base 400. In some embodiments, reference surface 420 has a complex shape, such as a spline-shape.

Other factors to consider include any coupling forces that may be used to secure first section 402 and second section 412, such as screws or fasteners that may compress first section 402 and/or second section 412. Thus, in some embodiments, these screws and fasteners are tightened down to the same extent as during a full assembly process in order to attain a more accurate measurement of distance y.

FIG. 4C shows first section 402 after second section 412 is removed and tool 424 is used to modify height x of protruding feature 404. In some embodiments, tool 424 is configured to apply heat to protruding feature 404 sufficient to a temperature sufficient to soften and deform protruding feature 404. In a particular embodiment, tool 424 is a heat-staking tool. In some embodiments, a pressure is also applied to protruding feature 404 so as to compress protruding feature 404 during the heating and softening until height x is reduced to desired height.

In some embodiments, height x is reduced a very small amount—in some instances less than a millimeter (i.e., on the scale of micrometers). Height x can be checked high accuracy using, for example a camera, laser measurement system or other suitable measurement system. The pressure can be applied in a substantially perpendicular direction with respect to mating surface 406 so as to ensure even height reduction. Additionally or alternatively, protruding feature 404 can be modified using one or more ultrasonic vibration, machining, laser melting, laser ablating and forging techniques. The technique(s) used can depend, in part, on the material of protruding feature 404. The amount in which height x is reduced will depend on distance y measured during the pre-assembly process shown in FIG. 4B. For example, height x can be reduced by distance y.

At FIG. 4D, second section 412 is coupled with first section 402. In some embodiments, a fastener or screw (not shown) is used to securely couple first section 402 and second section 412. The addition of adjusted protruding feature 404 results in first exterior surface 418 and second exterior surface 416 combine to form a continuous curved exterior surface to base 400 in accordance with reference surface 420, giving base 400 an aesthetically pleasing continuous look and feel. Note that even though gap 422 constitutes a break within reference surface 420, the overall shape of first exterior surface 418 and second exterior surface 416 is in accordance with reference surface 420. That is, there is substantially no negative or positive offset between second section 412 and first section 402.

It should be noted that that FIGS. 4A-4D show protruding feature 404 as part of first mating surface 406 of first section 402. In other embodiments, the protruding feature is positioned on second mating surface 414 of second section 412. In other embodiments, both first mating surface 406 and second mating surface 414 include protruding features, in which case the heights of one or more of the protruding features are modified.

It should also be noted that FIGS. 4A-4D show insert piece 403 as a discrete and separate member that is not integral to first section 402. This can be an advantageous design in that insert piece 403 can be easily removed and replaced with a new insert piece during reworks or during the lifecycle of the electronic device without having to replace the entirety of first section 402. In other embodiments, however, protruding feature 404 is an integral feature of first section 402. For example, protruding feature 404 can be constructed of the same material as first section 402. For instance, protruding feature 404 can be formed into first section 402 using a molding or machining operation. In a particular embodiment, first section 402 and protruding feature 404 are made of a thermoplastic material that is rigid enough to form an enclosure but also deformable to shape protruding feature 404 in response to applied heat and/or pressures.

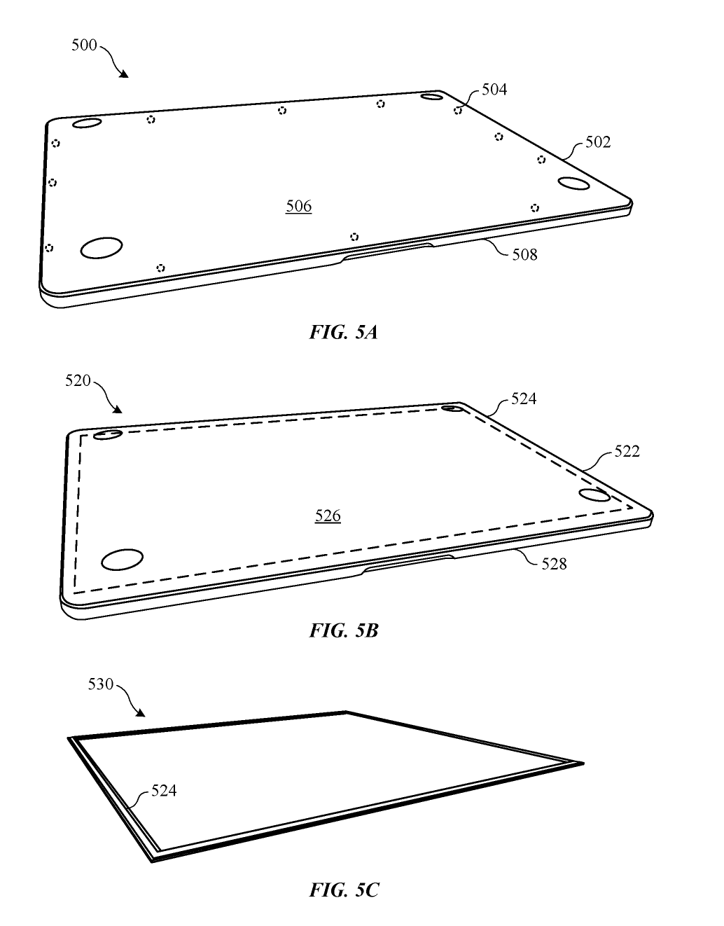

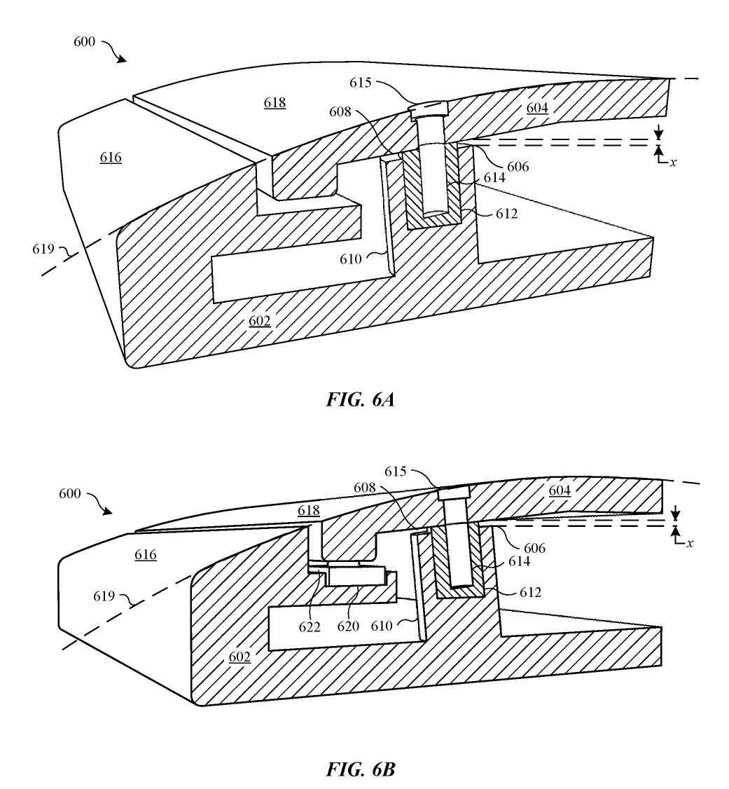

The shape and size of a protruding feature and/or an insert piece can vary. In addition, multiple protruding features and/or insert pieces can be used. FIGS. 5A-5C show some of these variations in accordance with some embodiments. FIGS. 5A-5C show perspective views of portable computers 500 and 520 having modified mating surfaces with different configurations. FIG. 5A shows portable computer 500 with base 502 having multiple protruding features 504 positioned on mating surfaces of first section 506 and/or second section 508 of base 502. Protruding features 504 are arranged around a perimeter of base 502, which can provide consistent offset control around the perimeter of base 502. This can also reduce any related warping of first section 506 relative to second section 508. In some embodiments, protruding features 504 are located proximate to fastening elements to reduce assembly-related stress induced in first section 506 and/or second section 508.

FIG. 5B shows portable computer 520 with protruding feature 524 having a rectangular shape in accordance with a perimeter of base 522. This arrangement also allows for consistent offset control and can reduce warping of first section 526 relative to second section 528. FIG. 5C shows a perspective view of insert piece 530 separated from base 522. Insert piece 530 includes rectangular shaped protruding feature 524.

FIGS. 6A-6B show cross section views of enclosure base 600, indicating other possible configurations of insert pieces. FIG. 6A shows base 600, which includes first section 602 that is configured to couple with second section 604 via a fastener (not shown). Base 600 includes first mating surface 606, which is configured to mate with second mating surface 608 of second section 604. First section 602 has standoff 610, which includes insert piece 612 with opening 614. Second section 604 includes corresponding opening 615 that aligns with opening 614 when second section 604 is mated with first section 602 and accommodates a fastener such as a screw. Insert piece 612 can be made of a different material than first section 602 and/or second section 604. In one embodiment, first section 602 and second section 604 are made of metal (e.g., aluminum alloy) and insert piece 612 is made of a thermoplastic material.

Height x of insert piece 612 is configured to be adjusted to compensate for offset between first section 602 and second section 604. In particular, a top surface of insert piece 612 can be reduced a predetermined amount such that first exterior surface 616 cooperates with second exterior surface 618 in accordance with reference surface 619. When a fastener is positioned within openings 614 and 615 and tighten down, this can create a localized downward force that can locally bend second exterior surface 618 proximate to opening 615, creating an undesirable bowing within second exterior surface 618. The placement of insert piece 612, therefore, is such that height x can specifically compensate for this tendency for localized bowing. For example, during a pre-assembly process, the fastener can be tightened down to the same extent as during a full assembly. This way, height x can be adjusted according to this tightened down state, resulting in second external surface 618 being free of any localized bowing.

FIG. 6B shows another embodiment where second insert piece 620 is also used to adjust first auxiliary mating surface 622 of first section 602. Second insert piece 620 is similar to the insert pieces described above with reference to FIGS. 4A-4D. This configuration allows the heights of both insert piece 612 and second insert piece 620 to be used to provide precise offset control across an entire exterior surface of enclosure base 600.

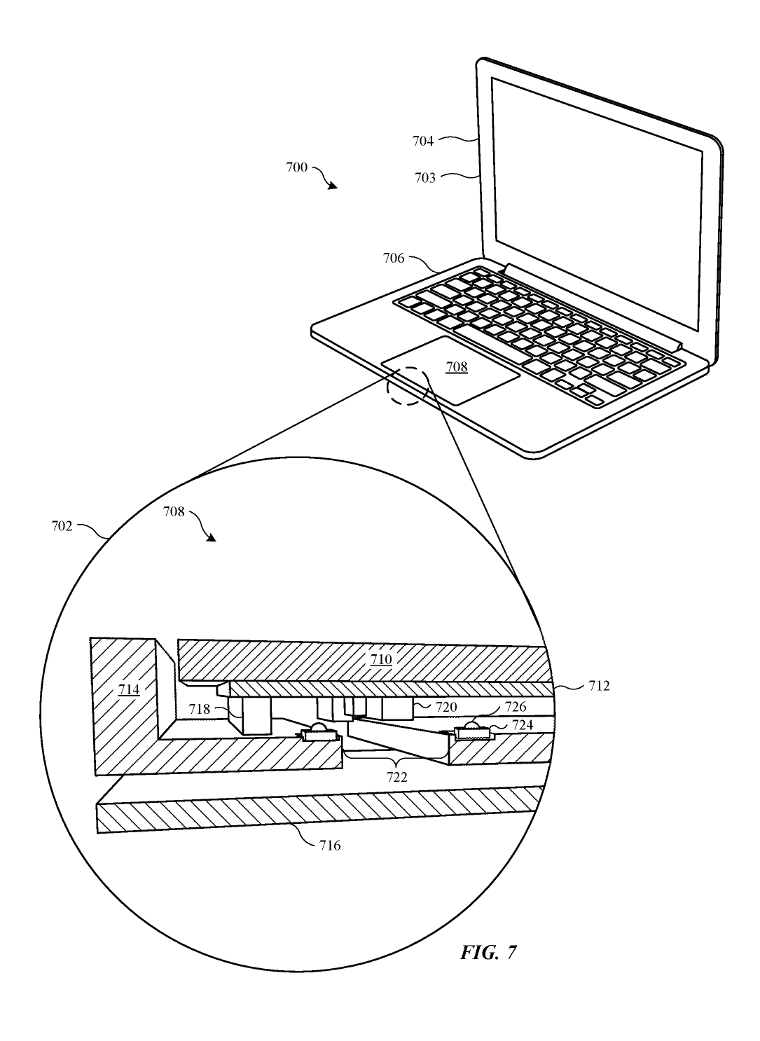

The methods described herein are not restricted to use in the manufacture of enclosures. That is, the methods can be applied to any suitable part having multiple components that are mated together or come in contact with each other. For example, an insert piece with an adjustable protruding feature can be used as adjustable stop mechanism, such as shown in FIG. 7.

FIG. 7 shows perspective view 700 and partial cross section view 702 of portable computer 703, which includes lid 704 and base 706. Base 706 includes track pad assembly 708, which has an input interface configured to respond to pressure from a user's finger. Cross section view 702 shows a close up view of track pad assembly 708, which includes cover glass 710 and printed circuit board (PCB) 712. Track pad assembly 708 is supported by enclosure piece 714, with compressible member 718 positioned between enclosure piece 714 and PCB 712. Compressible member 718 provides a back-force when a user presses cover glass 710, providing an up and down motion for track pad assembly 708. Compressible member 718 can be an elastomeric gel, spring, foam or any other suitable material or mechanism.

PCB 712 includes PCB components 720 attached thereto. Opening 722 within enclosure piece 714 accommodates PCB components 720 to keep enclosure piece 714 from blocking PCB components 720 and preventing the up and down motion of track pad assembly 708. Component 716, which in one embodiment is a battery cell, is positioned below opening 722. It can be difficult to accurately control offsets in relation to the movement of PCB components 720 in relation to component 716. For instance, PCB components 720 may touch component 716 when moving up and down, which can damage PCB components 720 and/or component 716. If enclosure piece 714 is very thin, this leaves very little tolerance for adjustments.

To address this problem, insert pieces 724 are positioned around opening 722 to act as stops and provide fine height adjustment of track pad assembly 708 in relation to component 716. That is, insert pieces 724 prevent track pad assembly 708 and PCB components 720 from moving too far downward during a press event. In particular, the heights of protruding features 726 of insert pieces 724 can be modified based on measurements taken during a pre-assembly process or after close measurements of critical dimensions of track pad assembly 708 and enclosure piece 714 are made. In some cases, the adjustments may be very small—on the scale of micrometers. For example, in some embodiments the heights of protruding features 726 is adjusted by between about 50 and 200 micrometers.

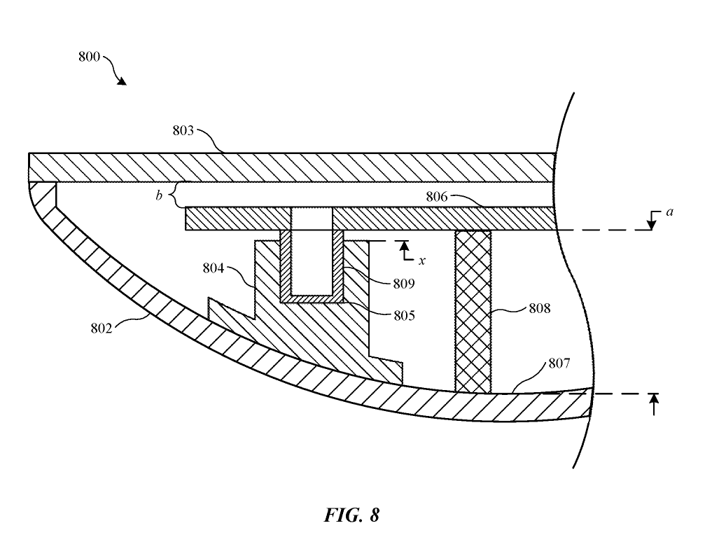

FIG. 8 shows a partial cross section view of electronic device 800, indicating another embodiment where an insert piece is used in conjunction with a fastener. Electronic device 800 includes enclosure 802 that cooperates with display screen 803 to enclose electrical components. In some embodiments, electronic device 800 is a desktop computer. Fastening member 804 is coupled with internal surface 807 of enclosure 802, and has opening 805 that is configured to accept a fastener, such as a screw, that secures component 806 to enclosure 802. In a particular embodiment, component 806 is a PCB that includes an input/output component 808 as part of a display assembly.

In some embodiments, internal surface 807 is curved, in some cases a spline shaped curve. Thus, the position of insert piece 809 along internal surface 807 can be critical for proper alignment of input/output component 808 in relation to other electronic components within enclosure 802. Critical dimensions can include, for example, distance a between component 806 and internal surface 807 of enclosure 802, as well as distance b between component 806 and display screen 803. Adjustable insert piece 809 is coupled within opening 805 of fastening member 804 in order to provide fine adjustments to achieve target critical distances a and b during the assembly process. In particular, a top surface of insert piece 809 can be modified to reduce height x at which insert piece 809 protrudes from fastening member 804.

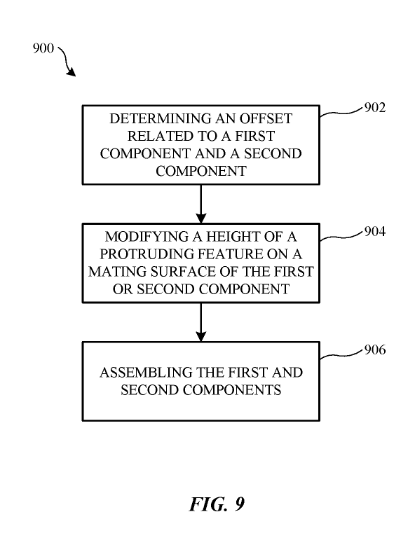

FIG. 9 shows flowchart 900 indicating a process for adjusting a datum surface for reducing an offset related to a first component and a second component of a part. The first and second components can be, for example sections of an enclosure for an electronic device, or different internal components within an enclosure for an electronic device. At 902, an offset value related to the first component and the second component is determined. In some embodiments, the offset value relates to an external surface of an enclosure, such as described above with reference to FIGS. 2, 3, 4A-4D, 5A-5C and 6A-6B. In other embodiments, the offset value relates to a distance between internal components, such as described above with reference to FIGS. 7 and 8.

In some embodiments, the offset value is determined by pre-assembling the first and second components together, measuring the offset value, and comparing the offset value to a desired offset. The measuring can be accomplished using a measuring system, such as a camera, laser measurement system, or other suitable measurement system. In other embodiments, the dimensions of the first and second components are measured separately such that the offset value is deduced.

At 904, a height of a protruding feature on a mating surface of the first or second component is modified. The protruding feature can be position on an insert piece that is separable from either the first or second component, or can be an integral feature on the first and/or second component. The insert piece can be made of the same material or a different material as the first and/or second component. In particular embodiments, the protruding feature is comprised of a thermoplastic material that is deformable upon applied heat and/or pressure, but cools to rigid form. The protruding feature can be modified using any suitable technique including heating, applying pressure, ultrasonic vibration, applying forging force, laser treatment, or any suitable combination thereof.

At 906, the first and second components are assembled together. In some cases, one or more fasteners, such as screws, are used to couple first and second components. In other embodiments, the first and second components are secured together using an adhesive. In some embodiments, a combination of fasteners and adhesive are used. The resultant part has critical dimensions that are within acceptable limits.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not target to be exhaustive or to limit the embodiments to the precise forms disclosed. It will be apparent to one of ordinary skill in the art that many modifications and variations are possible in view of the above teachings.

What is claimed is:

1. A method of adjusting an offset related to a first component and a second component, the first component configured to couple with the second component, the method comprising:
pre-assembling the first component with the second component, wherein the first component includes a mating surface having a protruding feature;
measuring an offset value related to the first component and the second component; and
modifying the mating surface by reducing a height of the protruding feature so as to reduce the offset value to a final offset value.

2. The method of claim 1, wherein the protruding feature is on a insert piece comprised of a first material, wherein the first component is comprised of a second material different than the first material.

3. The method of claim 1, wherein the protruding feature is comprised of the same material as that of the first component.

4. The method of claim 1, wherein reducing a height of the protruding feature comprises:
exposing the protruding feature to at least one of heat, pressure, ultrasonic vibration, forging force, and laser treatment.

5. The method of claim 4, wherein reducing a height of the protruding feature comprises applying pressure and heat to the protruding feature such that material of the protruding feature melts and deforms a shape of the protruding feature.

6. The method of claim 5, wherein applying the pressure and the heat comprises pressing on the protruding feature using a heated tool.

7. The method of claim 1, wherein the offset value corresponds to a distance that an external surface of the second component extends past a reference surface of a final part.

8. The method of claim 4, wherein the reference surface has a curved shape.

9. An enclosure for an electronic device, comprising:
a first section having a first mating surface with a protruding feature; and
a second section having a second mating surface configured to mate with the first mating surface, wherein a height of the protruding feature is adjusted such that a first external surface of the first section and a second external surface of the second section are aligned in accordance with a reference surface.

10. The enclosure of claim 9, wherein the protruding feature is part of an insert piece.

11. The enclosure of claim 10, wherein the insert piece is comprised of a different material than a material of the first section.

12. The enclosure of claim 10, wherein the insert piece is positioned within a pocket of the first section.

13. The enclosure of claim 10, wherein the insert piece is comprised of plastic and the first section is comprised of metal.

14. The enclosure of claim 10, wherein the insert piece has an opening configured to accommodate a fastener that secures the second section to the first section.

15. The enclosure of claim 9, wherein first mating surface comprises a plurality of protruding features.

16. A method of assembling an enclosure for an electronic device, the enclosure including a first section and a second section, the method comprising:
pre-assembling the enclosure by:
contacting a first mating surface of the first section with a second mating surface of the second section, the first mating surface including a protruding feature;
determining a degree of misalignment between the first section and the second section when the enclosure is pre-assembled;
modifying the first mating surface by reducing a height of the protruding feature, wherein the height is reduced to an extent that reduces the degree of misalignment; and
repeating the pre-assembling, determining and modifying until a desired degree of misalignment is achieved.

17. The method of claim 16, wherein the protruding feature is part of an insert piece positioned within a pocket of the first section.

18. The method of claim 16, wherein the protruding feature is an integral part of the first section.

19. The method of claim 16, wherein the degree of misalignment corresponds to a degree of protrusion of the second section with respect to a reference contour of the enclosure.

20. The method of claim 16, wherein the reference contour corresponds to a curved exterior surface of the enclosure.
